(19) United States
(12) Patent Application Publication
(10) Pub. No.: US 2007/0025408 A1
(43) Pub. Date: Feb. 1, 2007

(54) Long-wavelength VCSEL system with implant current confinement

(76) Inventors: Bernhard Ulrich Koelle, Milpitas, CA (US); Chung-Yi Su, Fremont, CA (US)

Correspondence Address: AVAGO TECHNOLOGIES, LTD., P.O. BOX 1920, DENVER, CO, 80201-1920, US

(21) Appl. No.: 11/193,171

(22) Filed: Jul. 29, 2005

(51) Int. Cl. H01S 5/00

(52) U.S. Cl. 372/50.124; 372/46.01

(57) ABSTRACT

The present invention provides a long-wavelength VCSEL system providing a buried layer, growing a top spacer layer on the buried layer, forming an active layer on the top spacer layer, and creating a current confinement structure in the buried layer with a post epitaxy ion implantation.

### CROSS-REFERENCE TO RELATED APPLICATION(S)

The present application contains subject matter related to a concurrently filed U.S. Patent Application by Bernhard Ulrich Koelle titled “Long-Wavelength VCSEL System with Heat Sink”. The related application is assigned to Agilent Technologies, Inc. and is identified by docket number 10050720-1.

### BACKGROUND

In the connected world, people create, transport, store, and consume vast amount of data from making a phone call, using the facsimile machine, and using the internet to name a few. We treat the technology that keeps people connected as ubiquitous and always available. Some of these technologies to transport the vast amount of data involve optics or lasers. One type of laser is called vertical cavity surface emitting laser (VCSEL) and is one of the technological components needed for the connected world. Market requirements demand that VCSEL manufacturability improves and price decreases.

VCSELs represent a relatively new class of semiconductor lasers. While there are many variations of VCSELs, one common characteristic is that they emit light perpendicular to a wafer's surface. In comparison to edge emitting lasers, this common VCSEL characteristic enables improved testing, improved manufacturing yield, and lowered cost. VCSELs can be formed from a wide range of material systems, e.g. material combinations and structures, to produce specific characteristics. In particular, the various material systems can be tailored to produce different laser wavelengths.

As VCSELs enter new markets and proliferate in existing markets, the requirements for better performance, manufacturing yield, lower cost, as well as growing system requirements stimulate developments for new structures and material systems. In particular, long-wavelength (1000 nm to 2000 nm) VCSEL exists but continue to be a large area for research and product development.

Thus, a need still remains for reliable current confinement and manufacturing for long-wavelength VCSEL system. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a long-wavelength VCSEL system providing a buried layer, growing a top spacer layer on the buried layer, forming an active layer on the top spacer layer, and creating a current confinement structure in the buried layer with a post epitaxy ion implantation.

Certain embodiments of the invention have other configurations in addition to or in place of those mentioned above. The configurations will become apparent to those skilled in the art from a reading of the following detailed description when taken with reference to the accompanying drawings.

### BRIEF DESCRIPTION OF THE DRAWINGS

FIG. 1A is a cross-sectional view of a long-wavelength VCSEL system with a heat sink and a backside contact, in an embodiment of the present invention;

FIG. 1B is a cross-sectional view of the long-wavelength VCSEL system of FIG. 1A in a formation phase of the heat sink;

FIG. 2 is a cross-sectional view of the optical cavity of the long-wavelength VCSEL system of FIG. 1A in a masking phase, after the formation phase of the heat sink;

FIG. 3 is a cross-sectional view of the optical cavity of the long-wavelength VCSEL system of FIG. 1A in an implantation phase, after the masking phase;

FIG. 4 is a cross-sectional view of the optical cavity of the long-wavelength VCSEL system of FIG. 1A in a shallow etch phase, after the implantation phase;

FIG. 5 is a cross-sectional view of the optical cavity of the long-wavelength VCSEL system of FIG. 1A in a deposition phase of the top metal, after the shallow etch phase;

FIG. 6 is a cross-sectional view of the optical cavity of the long-wavelength VCSEL system of FIG. 1A in a lift off phase, after the deposition phase of the top metal;

FIG. 7 is a cross-sectional view of the long-wavelength VCSEL system of FIG. 1A in the last phase shown, after the lift off phase;

FIG. 8 is a more detailed cross-sectional view of the active layer of the long-wavelength VCSEL system as shown in FIG. 1A;

FIG. 9 is a top view of the long-wavelength VCSEL system as shown in FIG. 1A;

FIG. 10 is a cross-sectional view of a long-wavelength VCSEL system with the heat sink and the backside contact, in an alternative embodiment of the present invention; and

FIG. 11 is a flow chart of a method for the long-wavelength VCSEL system in an embodiment of the present invention.

### BEST MODE FOR CARRYING OUT THE INVENTION

The following embodiments are described in sufficient detail to enable those skilled in the art to make and use the invention, and it is to be understood that other embodiments would be evident based on the present disclosure and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known structures, configurations, and process steps are not disclosed in detail. Likewise, the drawings showing embodiments of the device are semi-diagrammatic and not to scale and, particularly, some of the dimensions are for the clarity of presentation and are shown greatly exaggerated in the drawing FIGs. Similarly, although the sectional views in the drawings for ease of description show the exit ends of orifices as oriented upward, this arrangement in the FIGs. is arbitrary and is not intended to suggest that the delivery path should necessarily be in a upward direction. Generally, the device can be operated in any orientation. The same numbers are used in all the drawing FIGs. to relate to the same elements.

The term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane. The term “processing” as used herein includes deposition of material or photoresist, patterning, exposure, development, etching, cleaning, and/or removal of the material or photoresist as required in forming a described structure.

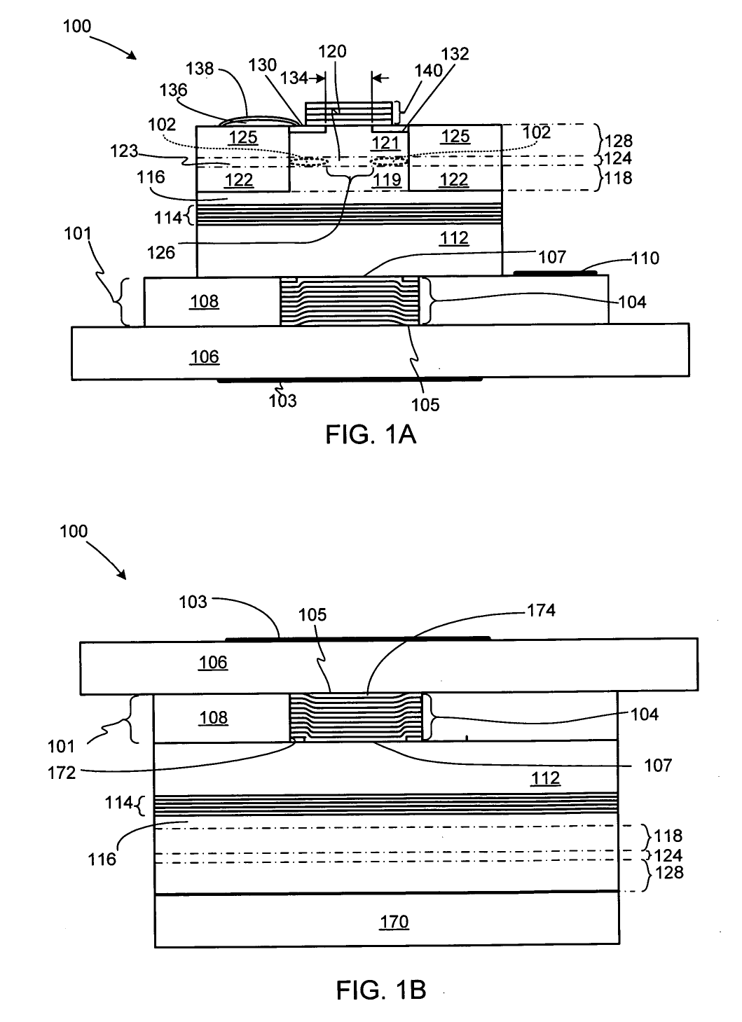

Referring now to FIG. 1A, therein is shown a cross-sectional view of a long-wavelength VCSEL system 100 with a heat sink 101 and a backside contact 103, in an embodiment of the present invention. The heat sink 101 is plated with a thermally conductive metal 108, such as gold. The long-wavelength VCSEL system 100 includes a bottom mirror 104 in the heat sink 101. The bottom mirror 104 includes a first surface 105 and a second surface 107. The second surface 107 and the bottom spacer layer 112 are attached. The heat sink 101 is attached to a wafer 106.

The backside contact 103 is attached to the wafer 106 on the opposing side bonded to the bottom mirror 104, wherein the backside contact 103 is used for electrically pumping the long-wavelength VCSEL system 100. As an alternative to the backside contact 103, a bottom contact 110 is formed on the heat sink 101 on a side opposite the wafer 106.

A bottom spacer layer 112, such as a p-type indium phosphide (InP) or InP-based material or n-type InP layer combined with a tunnel junction (not shown) inside the bottom spacer layer 112, is above the heat sink 101 and the bottom mirror 104. The bottom spacer layer 112 defines one end of the optical cavity. An active layer 114 is above the bottom spacer layer 112. The holes and electrons recombine resulting in photon emission in the active layer 114. A top spacer layer 116, such as an n-type indium phosphide (InP) or InP-based material, is above the active layer 114.

A first heterogeneous layer 118 is above the top spacer layer 116. The first heterogeneous layer 118 includes a first channel region 119 encircled by a first resistive region 122. The first channel region 119 may be the same material as the top spacer layer 116 with the same dopant level or different dopant level. The first resistive region 122 provides a higher electrical resistance than the first channel region 119 resulting in current flow within the first channel region 119.

A second heterogeneous layer 124 is above the first heterogeneous layer 118. The second heterogeneous layer 124 is the buried layer that includes a second channel region 120 encircled by a second resistive region 123. The second channel region 120 in the second heterogeneous layer 124 is a material, such as AlInAs, different than the material in the first channel region 119 of the first heterogeneous layer 118. For illustrative purposes, the second resistive region 123 is depicted the different as in the first resistive region 122, although it is understood that they may not be different, as well. Also for illustrative purposes, the material of the second heterogeneous layer 124 is depicted as different to the material of the first channel region 119, although it is understood that they may not be different, as well. The boundaries of the second resistive region 123 and the second channel region 120 align to the first resistive region 122 and the first channel region 119, respectively.

The partial outer volume of the second channel region 120 provides a current confinement structure 102 (to be described later). The current confinement structure 102 encircles and provides a current aperture 126. The current aperture 126 has a lower electrical resistance than the current confinement structure 102 such that current substantially flows through the current aperture 126.

A third heterogeneous layer 128 is above the second heterogeneous layer 124. The third heterogeneous layer 128 includes a third channel region 121 encircled by a third resistive region 125. The third channel region 121 is the same or similar material as the first heterogeneous layer 118 but with a higher dopant level for better electrical conductivity. The third resistive region 125 provides a higher electrical resistivity than the third channel region 121 resulting in current flow substantially within the third channel region 121. For illustrative purposes, the third resistive region 125 is the different from in the first resistive region 122, although it is understood that the third resistive region 125 and the first resistive region 122 may not be different, as well.

The boundary of the third resistive region 125 aligns to the first resistive region 122 and the second resistive region 123. The boundary of the third channel region 121 aligns to the first channel region 119 and the second channel region 120. The third heterogeneous layer 128 represents the other end of the optical cavity.

A top recess 132 is in the third heterogeneous layer 128, within the third channel region 121. A top metal 130 fills the top recess 132 within the third channel region 121 in the top surface of the third heterogeneous layer 128. The top recess 132 encircles a top aperture 134 of the third channel region 121. A polyimide spacer 136 is on a part of the third resistive region 125. To further reduce device capacitance, a top contact 138 is on the polyimide spacer 136 and connects to the top metal 130. For illustrative purposes, the top recess 132 is filled with the top metal 130, although it is understood that the top recess 132 may be partially filled with the top metal 130.

A top mirror 140 is above the top aperture 134 of the third heterogeneous layer 128 and covering the inner area of the top recess 132 with the top metal 130 in the top recess 132. The bottom of the top mirror 140 and the top of the bottom mirror 104 forms the optical cavity for the photons to resonate between the top mirror 140 and the bottom mirror 104. The optical cavity length must be a multiple of one half of the desired wavelength of the long-wavelength VCSEL system 100.

The top contact 138 and the backside contact 103 connect to an external bias for an electrically pumped VCSEL. The external bias generates current flow between the top contact 138 and the backside contact 103. The current stimulates the recombination of holes and electrons in the active layer 114 resulting in photon emission. These photons resonate between the top mirror 140 and the bottom mirror 104. The recombination process generates the majority of heat in the optical cavity. The heat sink 101 provides a thermally conductive path away from the active layer 114 and the current confinement structure 102 to the wafer 106. The heat sink 101 is below the current aperture 126 forming a low resistance path for current flow to the backside contact 103 resulting in limited current spreading. Alternatively, the bottom contact 110, not the backside contact 103, and the top contact 138 may be used for external bias connection.

For illustrative purposes, the long-wavelength VCSEL system 100 is depicted as having the current flow from the backside contact 103 or the bottom contact 110, depending on the external bias (not shown) connectivity, to the top contact 138 provided the bottom spacer layer 112 is p-type and the top spacer layer 116 is n-type. Although it is understood, the dopant types of the bottom spacer layer 112 and the top spacer layer 116, along with appropriate external bias connectivity, may be swapped resulting in the current flow in the opposite direction.

An external bias (not shown) connected to the backside contact 103 causes the current to flow from the backside contact 103 through the wafer 106 and the heat sink 101. The current continues to flow to the bottom spacer layer 112 of p-type, through the active layer 114, through the current aperture 126, through the top spacer layer 116 of n-type, to the top metal 130, and completing the circuit at the top contact 138.

A different external bias (not shown) connectivity causes the current to flow from the bottom contact 110 to the bottom spacer layer 112 of p-type. The current continues to flow through the active layer 114, the current aperture 126, the top spacer layer 116 of n-type, to the top metal 130, and completing the circuit at the top contact 138.

Referring now to FIG. 1B, therein is shown a cross-sectional view of the long-wavelength VCSEL system 100 of FIG. 1A in a formation phase of the heat sink 101. During this phase the long-wavelength VCSEL system 100 forms on a substrate 170, such as an InP or InP-based material and is shown in an orientation vertically flipped from FIG. 1A.

Prior to third heterogeneous layer 128, some sacrificial etch stop layers (not shown) may be grown on the substrate 170 to facilitate ease of removal of the substrate 170 at a later stage in the process. The third heterogeneous layer 128, such as InP or InP-based material, is grown on the sacrificial etch stop layers on the substrate 170. The third heterogeneous layer 128 is heavily doped forming an electrically conductive layer, such as n-type, providing a high electrical conductive layer for the top contact 138 (not shown) of FIG. 1A. The second heterogeneous layer 124, such as AlInAs, is grown on the third heterogeneous layer 128. The second heterogeneous layer 124 is doped as the same type, such as n-type, and to a lower dopant level as the third heterogeneous layer 128. The first heterogeneous layer 118, such as InP or InP-based material, is grown on the second heterogeneous layer 124. The first heterogeneous layer 118 is doped as the same type, such as n-type, and to a similar dopant level as the second heterogeneous layer 124.

The top spacer layer 116 is grown above the first heterogeneous layer 118. The top spacer layer 116 is doped as the same type, such as n-type, and to the similar dopant level as the first heterogeneous layer 118. For illustrative purposes, the top spacer layer 116 is shown as a separate layer to the first heterogeneous layer 118, although it is understood that the top spacer layer 116 may be part of the first heterogeneous layer 118.

The active layer 114 is grown on the top spacer layer 116, wherein the active layer 114 is typically intrinsic or very minimal doping. The bottom spacer layer 112 is grown on the active layer 114. The bottom spacer layer 112 is doped to a complementary type as the top spacer layer 116. For illustrative purposes, the top spacer layer 116 is shown doped as n-type resulting in the bottom spacer layer 112 doped as p-type.

A mask (not shown), such as photo resist, is placed on the bottom spacer layer 112 to protect a part of the bottom spacer layer 112. A seed metal 172 is deposited on the bottom spacer layer 112 by any number of processes such as thermal evaporation or physical vapor deposition (PVD). The seed metal 172 may be any number of metals or metallic compounds such as titanium or gold. The seed metal 172 assists the adhesion of the thermally conductive metal 108. Mask lift-off exposes part of the bottom spacer layer 112 between the seed metal 172.

The bottom mirror 104, such as a dielectric mirror, is deposited over the seed metal 172 and the bottom spacer layer 112 between the seed metal 172. The contour of the bottom mirror 104 follows the height provided by the seed metal 172 and the opening in the seed metal 172 to form a first recess 174 in the first surface 105. The bottom mirror 104 is selectively etched resulting in a predetermined lateral dimensions of the bottom mirror 104 minimally extending above the seed metal 172.

For illustrative purposes, the bottom mirror 104 is shown as a dielectric mirror, although it is understood that the bottom mirror 104 may be constructed by other materials, such as semiconductor materials that may be lattice matched to the material of the bottom spacer layer 112. The semiconductor material may be grown on the bottom spacer layer 112.

The thermally conductive metal 108 is plated on the seed metal 172 and self-aligned around the bottom mirror 104. After the plating process, the first recess 174 is filled with the thermally conductive metal 108, having optical reflective properties, resulting in an increased reflectivity of the bottom mirror 104. The thermally conductive metal 108 and the seed metal 172 form the structure of the heat sink 101. For illustrative purposes, the thermally conductive metal 108 surrounding the bottom mirror 104 is shown as a different material to the seed metal 172, although it is understood that the thermally conductive metal 108 may not be different to the seed metal 172, as well.

Bonding metal layers (not shown), such as palladium (Pa) or tantalum (Ta) based material, are applied on the heat sink 101 and the first surface 105 with a physical vapor deposition (PVD) or a similar process.

After the PVD process, the wafer 106 is bonded to the first surface 105 and the corresponding surface of the heat sink 101. Vertically above the lateral area of the bottom mirror 104, the backside contact 103 is attached to the wafer 106 on the side opposite to the bottom mirror 104, wherein the backside contact 103 is used for electrically pumping the long-wavelength VCSEL system 100. The wafer 106 is thermally and electrically conductive.

The substrate 170 is removed with selective etching exposing the third heterogeneous layer 128. A mask (not shown), such as photoresist, is used to protect the volumes below the mask of the first heterogeneous layer 118, the second heterogeneous layer 124, and the third heterogeneous layer 128. Implantation is applied damaging the material, such as a crystal, of the first heterogeneous layer 118, the second heterogeneous layer 124, and the third heterogeneous layer 128. The damages are crystal defects that eliminate free carriers in the material resulting in reduced conductivity. The reduced conductivity results in the first resistive region 122 shown in FIG. 1A, the second resistive region 123 shown in FIG. 1A, and the third resistive region 125 shown in FIG. 1A. There are a number of implantation processes such as oxygen implantation or transition metal implantation that may be used to create the crystal defects.

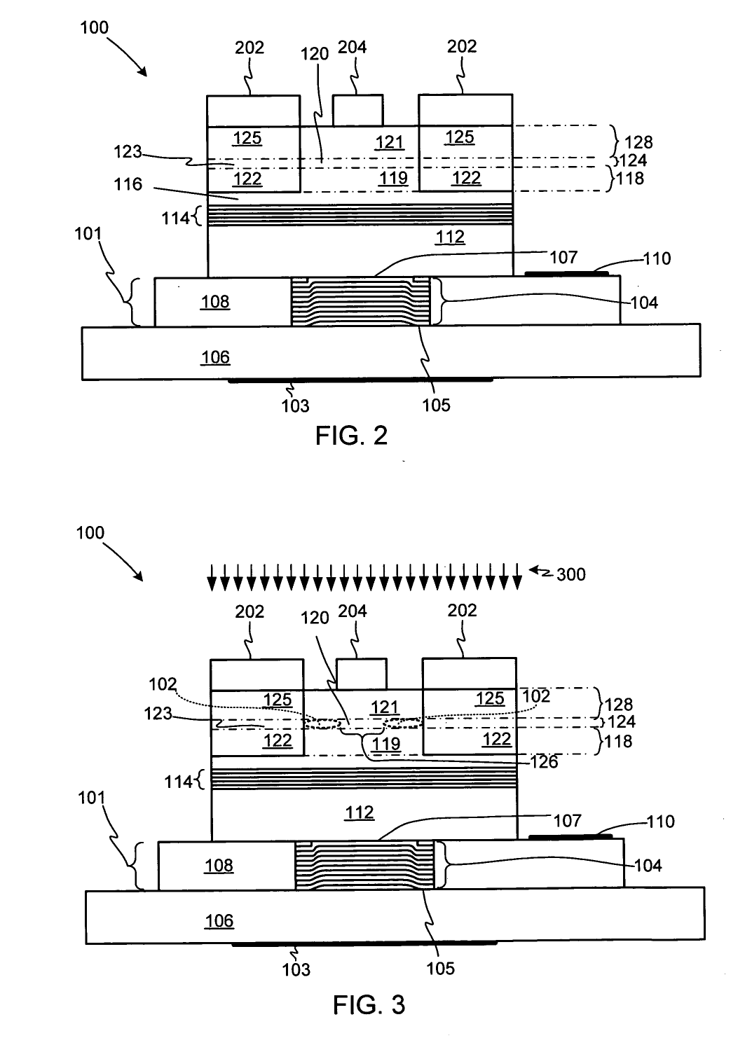

Referring now to FIG. 2, therein is shown a cross-sectional view of the optical cavity of the long-wavelength VCSEL system 100 of FIG. 1A in a masking phase, after the formation phase of the heat sink 101. During the masking phase and subsequent phases shown, the long-wavelength VCSEL system 100 is shown in the vertical orientation as shown in FIG. 1A. The heat sink 101, the bottom mirror 104, the wafer 106, the bottom contact 110, and the backside contact 103 are not shown for illustrative clarity. The long-wavelength VCSEL system 100 spanning the optical cavity length includes the bottom spacer layer 112 to the top of the third heterogeneous layer 128. The bottom spacer layer 112 is above the second surface 107 shown in FIG. 1A of the bottom mirror 104 shown in FIG. 1A and the corresponding surface of the heat sink 101 shown in FIG. 1A. An outer mask 202 protects the first resistive region 122, the second resistive region 123, and the third resistive region 125 from subsequent processing until it is removed. A middle mask 204 protects part of the first channel region 119, the second channel region 120, and the third channel region 121 from subsequent processing until it is removed. Note, the current confinement structure 102 shown in FIG. 1A in the second heterogeneous layer 124 is not yet formed. During the masking phase, the current confinement structure 102 is electrically conductive as is the second channel region 120. For illustrative purposes, implantation protection is shown as including the outer mask 202, although it is understood the outer mask 202 may not be needed.

Referring now to FIG. 3, therein is shown a cross-sectional view of the optical cavity of the long-wavelength VCSEL system 100 of FIG. 1A in an implantation phase, after the masking phase. During this phase, the post epitaxy ion implantation damages the material of the second channel region 120 with little or no damage to the material in the first channel region 119 and the third channel region 121 under the area not protected by the outer mask 202 and the middle mask 204.

The ion implantation damage leads to the formation of defects characterized by dangling bonds. As increasing densities of defects are produced by the ion implantation, the Fermi level moves within the band gap towards the middle, thus rendering the unprotected part of the second heterogeneous layer 124 as resistive and creating the current confinement structure 102.

The current confinement structure 102 encircles and forms the current aperture 126. The current confinement structure 102 confines the current flow through the current aperture 126. The current aperture 126 vertically aligns within the area of the bottom mirror 104 shown in FIG. 1A. For illustrative purposes, the current confinement structure 102 resulting from ion implantation has gain guiding properties with weak index guiding properties, although it is understood that other implantation processes could be used to create the current confinement structure 102 with strong index guiding.

The range and degree of damage produced by the ion implantation depends on the doses and dose rate, as well as the temperature of the device during the implantation. The ion implantation does not significantly damage the first channel region 119 and the third channel region 121, thus maintaining a lower electrical resistance. Any damage that may occur in the first channel region 119 and the third channel region 121 may be self correcting or may be corrected with moderate temperature annealing, such as approximate range of 300° C. to 400° C. The second heterogeneous layer 124 placement and the ion implantation range are sufficiently spaced from the active layer 114 so as not to cause damage to the active layer 114.

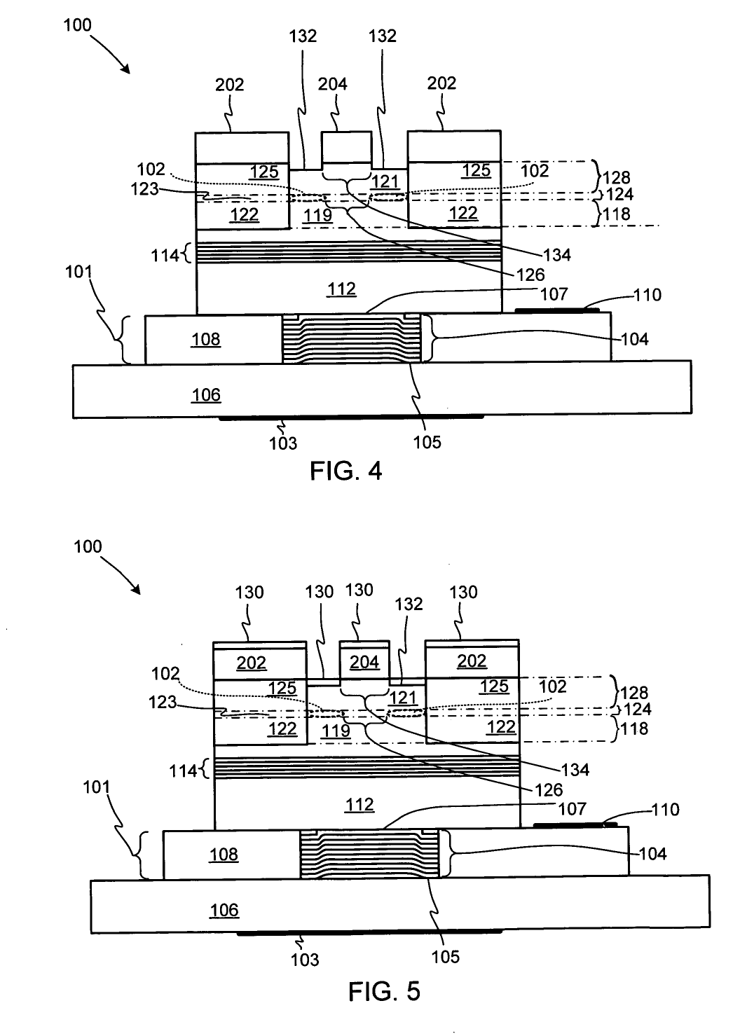

Referring now to FIG. 4, therein is shown a cross-sectional view of the optical cavity of the long-wavelength VCSEL system 100 of FIG. 1A in a shallow etch phase, after the implantation phase. During this phase, the top surface of the third channel region 121 not protected by the outer mask 202 or the middle mask 204 is etched resulting in the top recess 132. The top recess 132 has similar lateral dimensions to the current confinement structure 102. The top recess 132 encircles and forms the top aperture 134 that is aligned with the current aperture 126.

For illustrative purposes, the lateral dimension of the top recess 132 is similar to the current confinement structure 102, although it is understood that it may differ. It is also understood that the number, and depth of the top recess 132 may differ. At this phase, the top recess 132 exits to air providing a lower refractive index creating an index step to form an index guide for the optical path. The top recess 132 for creating the index step is at the edge of the emission area. The closer the index step is to the active layer 114, the more effective it is in producing the index guide. The distance between the index step and the active layer 114, may vary due to several dimensions, such as shorter optical cavity length or the top recess 132 being deeper.

Referring not to FIG. 5, therein is shown a cross-sectional view of the long-wavelength VCSEL system 100 of FIG. 1A spanning the optical cavity length in a deposition phase of the top metal 130, after the shallow etch phase. During this phase, the top metal 130 is deposited in the top recess 132 which it may fill partially or fully using standard metal processes. The top metal 130 provides a path for current flow through the active layer 114. The top aperture 134 encircled by the top metal 130 provides an area for the photons to resonate in the optical cavity as well as an area for photon emission. The top recess 132 or the top metal 130 or the combination thereof decrease the effective optical cavity length and provide an index guide.

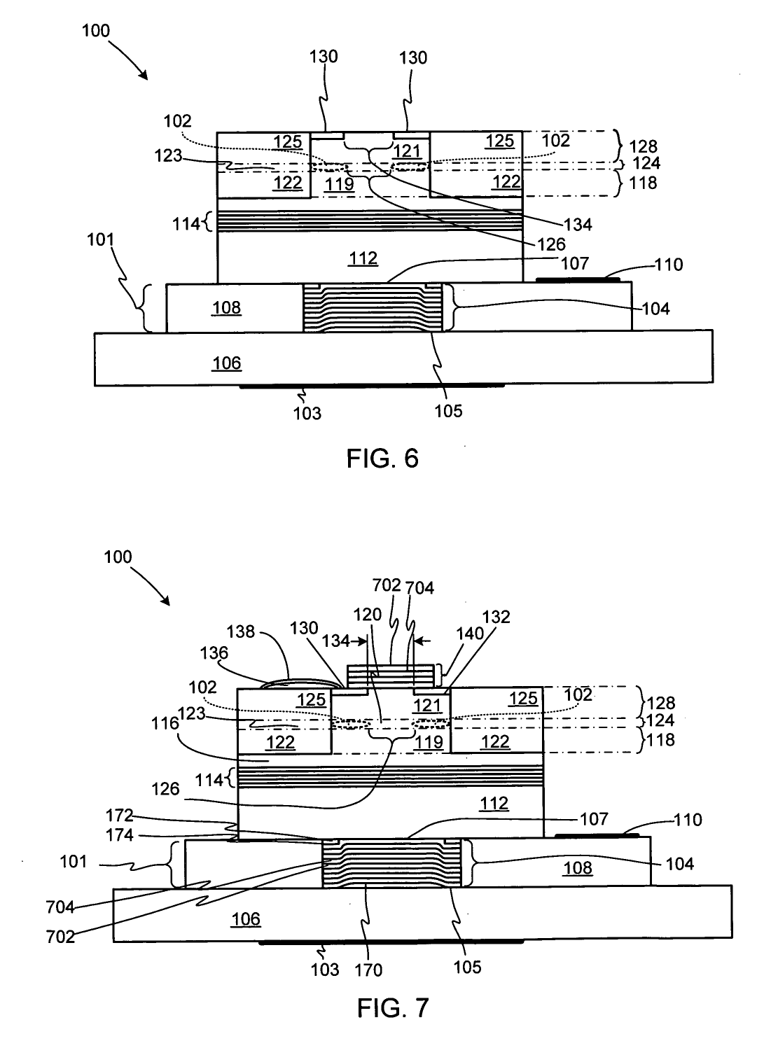

Referring now to FIG. 6, there is shown a cross-sectional view of the optical cavity of the long-wavelength VCSEL system 100 of FIG. 1A in a lift off phase, after the deposition phase of the top metal 130. During this phase, the outer mask 202 of FIG. 5 and the middle mask 204 of FIG. 5 are lifted off leaving the top metal 130 and the current confinement structure 102. Also the top surface of the third heterogeneous layer 128 is exposed for additional processing.

Referring now to FIG. 7, therein is shown a cross-sectional view of the long-wavelength VCSEL system 100 in the last phase shown, after the lift off phase. This cross-sectional view also shows the wafer 106, the heat sink 101 including the thermally conductive metal 108, the bottom contact 110, the bottom mirror 104, the top mirror 140, the polyimide spacer 136, and the top contact 138 along with the optical cavity of the long-wavelength VCSEL system 100. During this phase, the top mirror 140 is grown or is deposited, depending on the material used for the top mirror 140, on the third heterogeneous layer 128. The top mirror 140 is etched to the lateral dimensions covering the top aperture 134 and the partial inner area of the top metal 130.

The lateral dimensions of optical cavity of the long-wavelength VCSEL system 100 is etched exposing the heat sink 101. An alternative to the backside contact 103, the bottom contact 110 is formed on the heat sink 101. The polyimide spacer 136 is also placed on a part of the third resistive region 125. The top contact 138 is deposited on the polyimide spacer 136 and connects to the top metal 130.

The top mirror 140 and the bottom mirror 104 are formed of multiple layer pairs of complementary refractive material. The multiple layer pairs create an alternating structure where each layer pair includes a high refractive layer 702 and a low refractive layer 704. Such a complementary layer pair can be made from a number of different combinations of materials including semiconductor layers, dielectric materials such as TiO₂ (titanium dioxide) for the high refractive layer 702 and SiO₂ (silicon dioxide) for the low refractive layer 704 or hybrid combinations of semiconductor, dielectric and metal layers. Materials and construction determine the type of reflector such as a “dielectric” distributed Bragg reflector (DBR) or a semiconductor DBR or a metal DBR. The top mirror 140 may also create an index guide with a notch (not shown) at the outer periphery at the upper edge of the top mirror 140 outside the optical path.

For illustrative purpose, the present invention discloses the top mirror 140 and the bottom mirror 104 as dielectric DBR, but it is understood that the present invention can be implemented with other semiconductor or metal DBR. It is further understood that different compounds such as quaternary compounds of indium gallium aluminum arsenide (InGaAlAs), or indium gallium aluminum arsenide phosphide (InGaAlAsP), or aluminum gallium arsenide antimonide (AlGaAsSb), and aluminum gallium phosphide antimonide (AlGaPSb) may be used as the high refractive layer 702 in combination with the low refractive layer 704 such as binary indium phosphide layers, ternary indium/aluminum/arsenic (InAlAs), aluminun/arsenic/antimony (AlAsSb) or aluminum/phosphorous/antimony (AlPSb) layers.

For illustrative purpose, the high refractive layer 702 and the low refractive layer 704 of the top mirror 140 and of the bottom mirror 104 are depicted as the same. Although it is understood the materials for the high refractive layer 702 and the low refractive layer 704 may be the same for the top mirror 140 and the bottom mirror 104 with a different number of layers. The bottom mirror 104 has more pairs of the high refractive layer 702 and the low refractive layer 704 for more reflectivity than the top mirror 140. It is further understood that the top mirror 140 and the bottom mirror 104 may have different materials for the high refractive layer 702 and the low refractive layer 704. It is also understood that the top mirror 140 and the bottom mirror 104 may be of different construction.

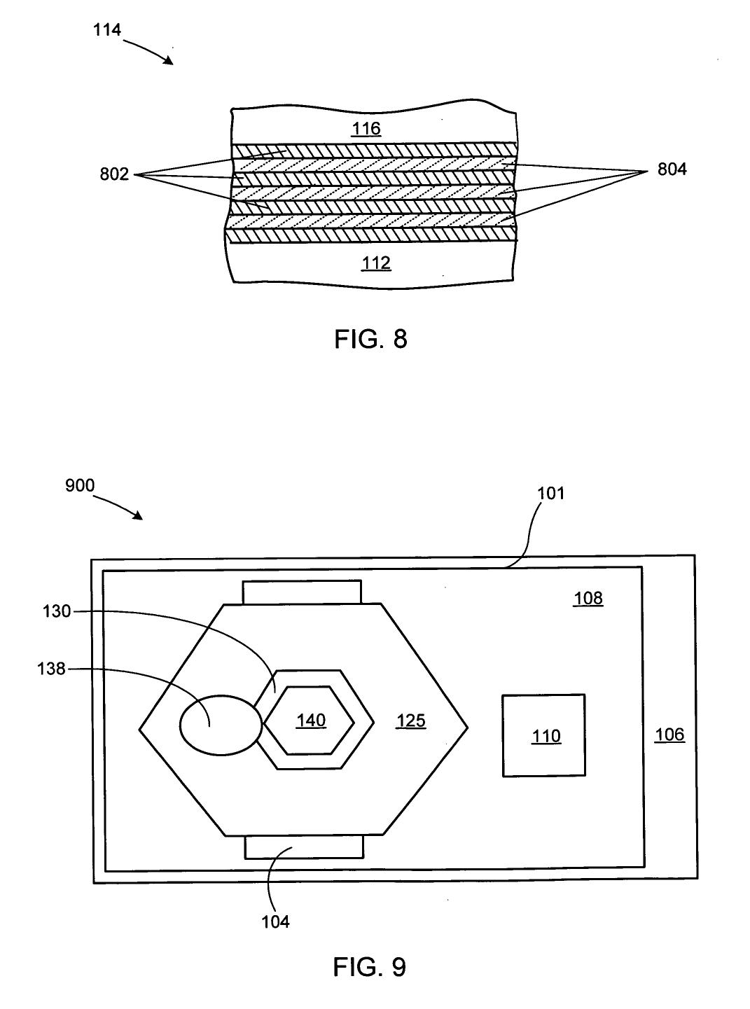

Referring now to FIG. 8, therein is shown a more detailed cross-sectional view of the active layer 114 of the long-wavelength VCSEL system 100 as shown in FIG. 1A. The active layer 114 includes one or more quantum wells. The quantum wells, which typically include a quantum well layer 802, sandwiched by a pair of a barrier layer 804, are the layers into which carriers, i.e., electrons and holes, are injected. The electrons and holes recombine in the active layer 114 and emit photons at a wavelength determined by the material layers in the quantum well. The quantum well layer 802 includes a low band gap semiconductor material, while the barrier layer 804 has a band gap higher than the band gap of the quantum well layer 802. When the device is subject to forward bias, electrons and holes are injected into and trapped in the quantum well layer 802 and recombine to emit coherent light at a particular wavelength.

For illustrative purposes, the active layer 114 is depicted as an indium phosphide based active layer, such as the material pair for the quantum well layer 802 and the barrier layer 804 of InGaAsP and InGaAsP, respectively, or of InGaAs and InP, respectively. The materials used for the quantum well layer 802 and the barrier layer 804 provide lattice matching between these layers as well as with the bottom spacer layer 112 and the top spacer layer 116. Also for illustrative purposes, the active layer 114 are shown to include the quantum wells, although it is understood the active layer 114 may include other active material, such as quantum wires or quantum dots.

Referring now to FIG. 9, therein is shown a top view 900 of the long-wavelength VCSEL system 100 as shown in FIG. 1A. The top view depicts the top mirror 140 in the shape of a hexagon, although it is understood the top mirror 140 may be other shapes, such as circular, rectangular, elliptical, that meet the system design requirements. The hexagonal region beyond the periphery of the top mirror 140 is the outer area of the top metal 130.

Similar to the shape of the top mirror 140, the top metal 130 is shown in the shape of a hexagon, although it is understood the top metal 130 may be other shapes, such as circular, rectangular, elliptical, that meet the system design requirements. It is also understood the top metal 130 may be a shape different than the top mirror 140 as long as the top aperture 134 of FIG. 1A is covered by the top mirror 140 and the top metal 130 is accessible to the top contact 138. The region beyond the top metal 130 periphery is the third resistive region 125 also depicted as a shape of a hexagon. Although it is understood, the third resistive region 125 may be other shapes, such as circular, rectangular, elliptical, that meet the system design requirements. Below the third resistive region 125 is the bottom mirror 104 with the heat sink 101 surrounding the bottom mirror 104 and the thermally conductive metal 108. The top view also depicts the bottom contact 110 on the heat sink 101. The wafer 106 can be seen beyond the periphery of the heat sink 101.

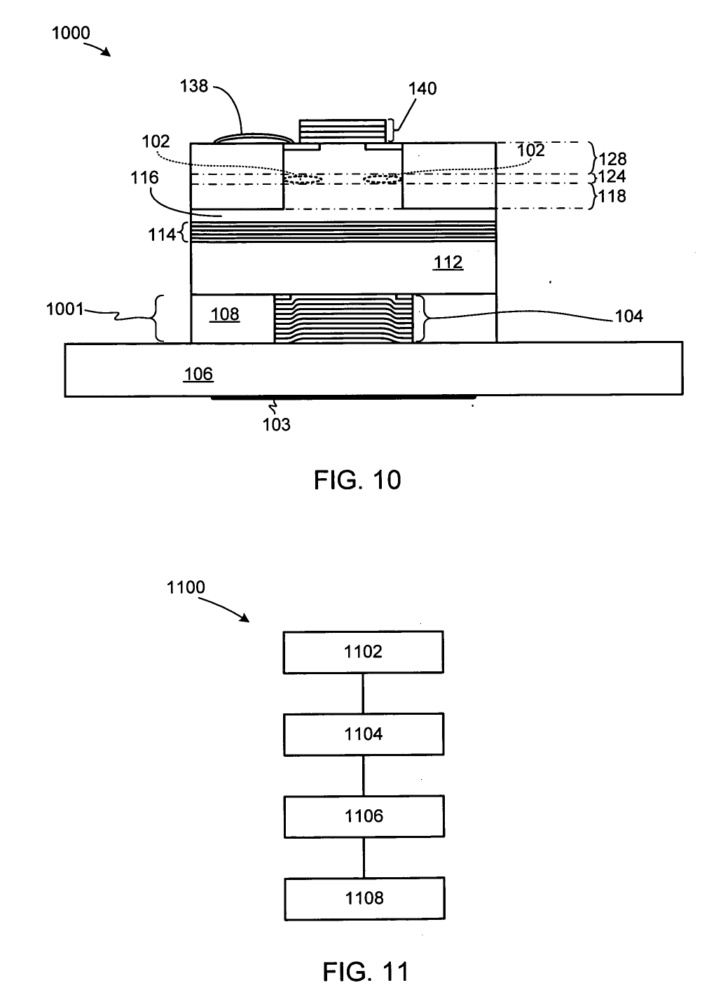

Referring now to FIG. 10, therein is shown a cross-sectional view of a long-wavelength VCSEL system 1000 with a heat sink 1001 and the backside contact 103, in an alternative embodiment of the present invention. In a manner similar in FIG. 1A, the long-wavelength VCSEL system 1000 is electrically pumped using the top contact 138 and the backside contact 103. The lateral dimension of the heat sink 1001 is less than the lateral dimensions of the heat sink 101 (not shown) of FIG. 1A such that the lateral dimensions of the heat sink 1001 aligns with the bottom spacer layer 112. The heat sink 1001 is similarly plated with the thermally conductive metal 108. The long-wavelength VCSEL system 1000 provides only the top contact 138 and the backside contact 103 for external bias (not shown) connections for electrical pumping.

Similar to the long-wavelength VCSEL system 100, the long-wavelength VCSEL system 1000 is mounted on the wafer 106 and includes the top mirror 140 and the bottom mirror 104. The bottom spacer layer 112 is above the bottom mirror 104 and the heat sink 1001. The active layer 114 is formed above the bottom spacer layer 112 followed by the formation of the top spacer layer 116 above the active layer 114. The first heterogeneous layer 118, the second heterogeneous layer 124 with the current confinement structure 102, and the third heterogeneous layer 128 forms above the top spacer layer and below the top mirror 140.

Referring now to FIG. 11, therein is shown a flow chart of a method 1100 for the long-wavelength VCSEL system 100 in an embodiment of the present invention. The method 1100 includes providing a buried layer in a block 1102; growing a top spacer layer on the buried layer in a block 1104; forming an active layer on the top spacer layer in a block 1106; and creating a current confinement structure in the buried layer with a post epitaxy ion implantation in a block 1108.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations which fall within the scope of the included claims. All matters hithertofore set forth herein or shown in the accompanying drawings are to be interpreted in an illustrative and non-limiting sense.

The invention claimed is:

1. A long-wavelength VCSEL system comprising:
providing a buried layer;
growing a top spacer layer on the buried layer;
forming an active layer on the top spacer layer; and
creating a current confinement structure in the buried layer with a post epitaxy ion implantation.

2. The system as claimed in claim 1 wherein forming the active layer on the top spacer layer comprises forming the active layer a predetermined distance above the buried layer, wherein the post epitaxy ion implantation damages the buried layer and the post epitaxy ion implantation does not damage the active layer.

3. The system as claimed in claim 1 wherein creating the current confinement structure in the buried layer with the post epitaxy ion implantation comprises forming a current aperture encircled by the current confinement structure.

4. The system as claimed in claim 1 wherein creating the current confinement structure in the buried layer with a post epitaxy ion implantation comprises providing a resistive region lateral to the current confinement structure.

5. The system as claimed in claim 1 wherein creating the current confinement structure in the buried layer with the post epitaxy ion implantation comprises damaging the buried layer with the post epitaxy ion implantation and minimally damaging the top spacer layer with the post epitaxy ion implantation.

6. A long-wavelength VCSEL system comprising:
providing a third heterogeneous layer;
growing a second heterogeneous layer on the third heterogeneous layer;
growing a first heterogeneous layer on the second heterogeneous layer;
growing a top spacer layer on the first heterogeneous layer;
forming an active layer on the top spacer layer; and
creating a current confinement structure in the second heterogeneous layer with a post epitaxy ion implantation.

7. The system as claimed in claim 6 wherein forming the active layer on the top spacer layer comprises forming the active layer at the predetermined distance above the second heterogeneous layer, wherein the post epitaxy ion implantation damages the second heterogeneous layer and the post epitaxy ion implantation does not damage the active layer.

8. The system as claimed in claim 6 wherein creating the current confinement structure in the second heterogeneous layer with the post epitaxy ion implantation comprises damaging the second heterogeneous layer with the post epitaxy ion implantation and minimally damaging the third heterogeneous layer, the first heterogeneous layer, and the top spacer layer with the post epitaxy ion implantation.

9. The system as claimed in claim 6 further comprising etching a notch in the outer periphery at the upper edge of the top mirror at the edge of the optical path as an index guide.

10. The system as claimed in claim 6 further comprising etching a recess at the edge of the emission area as an index step.

11. A long-wavelength VCSEL system comprising:
a buried layer;
a top spacer layer on the buried layer;
an active layer on the top spacer layer; and
a current confinement structure in the buried layer with a post epitaxy ion implantation.

12. The system as claimed in claim 11 wherein the active layer on the top spacer layer comprises the active layer a predetermined distance above the buried layer, wherein the post epitaxy ion implantation damages the buried layer and the post epitaxy ion implantation does not damage the active layer.

13. The system as claimed in claim 11 wherein the current confinement structure in the buried layer with the post epitaxy ion implantation comprises a current aperture encircled by the current confinement structure.

14. The system as claimed in claim 11 wherein the current confinement structure in the buried layer with a post epitaxy ion implantation comprises a resistive region lateral to the current confinement structure.

15. The system as claimed in claim 11 wherein the current confinement structure in the buried layer with the post epitaxy ion implantation comprises the buried layer damaged with the post epitaxy ion implantation and the top spacer layer minimally damaged with the post epitaxy ion implantation.

16. The system as claimed in claim 11 further comprising:
a third heterogeneous layer;
a second heterogeneous layer on the third heterogeneous layer;
a first heterogeneous layer on the second heterogeneous layer;
the top spacer layer on the first heterogeneous layer;
the active layer on the top spacer layer; and
the current confinement structure in the second heterogeneous layer with the post epitaxy ion implantation.

17. The system as claimed in claim 11 wherein the active layer on the top spacer layer comprises the active layer at the predetermined distance above the second heterogeneous layer, wherein the post epitaxy ion implantation damages the second heterogeneous layer and the post epitaxy ion implantation does not damage the active layer.

18. The system as claimed in claim 11 wherein the current confinement structure in the second heterogeneous layer with the post epitaxy ion implantation comprises the second heterogeneous layer damaged with the post epitaxy ion implantation and the third heterogeneous layer, the first heterogeneous layer, and the top spacer layer minimally damaged with the post epitaxy ion implantation.

19. The system as claimed in claim 11 further comprising a notch in the outer periphery at the upper edge of the top mirror at the edge of the optical path as an index guide.

20. The system as claimed in claim 11 further comprising a recess at the edge of the emission area as an index step.
